(19) United States
(12) Patent Application Publication
(10) Pub. No.: US 2026/0162936 A1
(43) Pub. Date: Jun. 11, 2026

(54) PLASMA GENERATOR AND SUBSTRATE PROCESSING APPARATUS INCLUDING THE SAME

(71) Applicant: SAMSUNG ELECTRONICS CO., LTD., Suwon-si (KR)

(72) Inventors: Donghyun JANG, Suwon-si (KR); Giduck KWEON, Suwon-si (KR); Min SON, Suwon-si (KR); Young-Joon AHN, Suwon-si (KR); Taewoong OH, Suwon-si (KR); Heesu YU, Suwon-si (KR); Kyuchol LEE, Suwon-si (KR); Hunhee LEE, Suwon-si (KR); Enje CHOI, Suwon-si (KR); Sunghyun HAN, Suwon-si (KR)

(73) Assignee: SAMSUNG ELECTRONICS CO., LTD., Suwon-si (KR)

(21) Appl. No.: 19/179,423

(22) Filed: Apr. 15, 2025

(30) Foreign Application Priority Data
Oct. 7, 2024 (KR) 10-2024-0136068

(51) Int. Cl. H01J 37/32; H10P 72/10

(52) U.S. Cl. CPC H01J 37/32091; H01J 37/32449; H01J 37/3255; H01J 37/32568; H01J 37/32715; H01J 2237/327; H10P 72/12

(57) ABSTRACT

Provided is a plasma generator and a substrate processing apparatus including same. The plasma generator includes: a housing including an internal space and an opening through which plasma is emitted; a gas nozzle in the internal space, wherein the gas nozzle is configured to inject a processing gas into the internal space; a plurality of plasma electrodes on an outer surface of the housing and to which a voltage is applied; and a plurality of floating electrodes on the outer surface of the housing and adjacent to the plurality of plasma electrodes.

### CROSS-REFERENCE TO RELATED APPLICATION

This application claims priority to Korean Patent Application No. 10-2024-0136068, filed in the Korean Intellectual Property Office on Oct. 7, 2024, the entire contents of which are incorporated herein by reference.

### BACKGROUND

### 1. Field

The present disclosure relates to a plasma generator and a substrate processing apparatus including the same.

### 2. Description of the Related Art

A low temperature is essential in a memory manufacturing process (particularly, a process of manufacturing a dynamic random access memory (DRAM) product) due to miniaturization of a semiconductor element. Processes using plasma are increasing due to a demand for the low temperature associated with such processes. In particular, a batch type equipment using plasma is widely used in a deposition process.

However, a particle may be generated in a plasma box (i.e., an apparatus that generates plasma) through a repeated process in a batch equipment, and the particle may have a significant bad influence on a product yield. Accordingly, a method capable of reducing the formation of such particles while implementing the same plasma effect as that of a conventional art is being researched.

### SUMMARY

Provided is a plasma generator with improved plasma efficiency and a substrate processing apparatus including the same.

Further provided is a plasma generator capable of providing a uniform deposition thickness on a substrate and a substrate processing apparatus including the same.

According to an aspect of the disclosure, a plasma generator includes: a housing including an internal space and an opening through which plasma is emitted; a gas nozzle in the internal space, wherein the gas nozzle is configured to inject a processing gas into the internal space; a plurality of plasma electrodes on an outer surface of the housing and to which a voltage is applied; and a plurality of floating electrodes on the outer surface of the housing and adjacent to the plurality of plasma electrodes.

According to an aspect of the disclosure, a plasma generator includes: a first outer wall extending in a first direction from a first area to a second area; a second outer wall parallel to the first outer wall and extending in from a third area to a fourth area; a third outer wall extending in a second direction from the first area to the third area, wherein the second direction intersects the first direction; a gas nozzle in an inner space formed by the first, the second, and the third outer walls, wherein the gas nozzle is configured to inject a processing gas into the inner space; a first plasma electrode on an outer surface of the first outer wall and a second plasma electrode on an outer surface of the second outer wall, wherein a voltage is applied to the first and the second plasma electrodes; a first floating electrode on the outer surface of the first outer wall and a second floating electrode on the outer surface of the second outer wall, wherein the first floating electrode is adjacent to the first plasma electrode and the second floating electrode is adjacent to the second plasma electrode; and a gas guide on inner surfaces of the first outer wall and the second outer wall.

According to an aspect of the disclosure, a substrate processing apparatus includes: a reaction vessel; a wafer boat in the reaction vessel and configured to hold one or more wafers; and a plasma generator configured to generate plasma, wherein the plasma generator includes: a housing including an internal space and an opening through which the plasma is emitted into the reaction vessel; a gas nozzle in the internal space, wherein the gas nozzle is configured to inject a processing gas into the internal space; a plurality of plasma electrodes on an outer surface of the housing and to which a voltage is applied; and a plurality of floating electrodes on an outer surface of the housing and adjacent to the plurality of plasma electrodes.

### BRIEF DESCRIPTION OF THE DRAWINGS

The above and other aspects and features of certain embodiments of the present disclosure will be more apparent from the following description taken in conjunction with the accompanying drawings, in which:

FIG. 1 is a diagram illustrating a substrate processing apparatus according to one or more embodiments of the present disclosure;

FIG. 2 is a diagram illustrating an X-Y cross-section of the substrate processing apparatus shown in FIG. 1;

FIG. 3 is a diagram illustrating an X-Y cross-section of the substrate processing apparatus shown in FIG. 1;

FIG. 4 is a diagram for describing a plasma generator according to one or more embodiments of the present disclosure;

FIG. 5 is a diagram for describing a plasma generator according to one or more embodiments of the present disclosure;

FIG. 6 is a diagram for describing a plasma generator according to one or more embodiments of the present disclosure;

FIG. 7 is a diagram for describing a plasma generator according to one or more embodiments of the present disclosure;

FIG. 8 is a diagram for describing a plasma generator according to one or more embodiments of the present disclosure;

FIG. 9 is a diagram for describing a plasma generator according to one or more embodiments of the present disclosure;

FIG. 10 is a diagram for describing a plasma generator according to one or more embodiments of the present disclosure;

FIG. 11 is a diagram for describing a plasma generator according to one or more embodiments of the present disclosure;

FIG. 12 is a diagram for describing a plasma generator according to one or more embodiments of the present disclosure;

FIG. 13 is a diagram for describing a plasma generator according to one or more embodiments of the present disclosure;

FIG. 14 is a diagram for describing a plasma generator according to one or more embodiments of the present disclosure;

FIG. 15 is a diagram for describing a plasma generator according to one or more embodiments of the present disclosure;

FIG. 16 is a diagram for describing a plasma generator according to one or more embodiments of the present disclosure;

FIG. 17 is a diagram for describing a plasma generator according to one or more embodiments of the present disclosure;

FIG. 18 is a diagram for describing a plasma generator according to one or more embodiments of the present disclosure;

FIG. 19 is a diagram for describing a shape of an electrode according to one or more embodiments of the present disclosure;

FIG. 20 is a diagram for describing a shape of an electrode according to one or more embodiments of the present disclosure; and

FIG. 21 is a diagram for describing a shape of an electrode according to one or more embodiments of the present disclosure.

### DETAILED DESCRIPTION

One or more embodiments of the present disclosure are described more fully hereinafter with reference to the accompanying drawings. The present disclosure may be modified in various ways, all without departing from the spirit or scope of the present disclosure.

In order to clearly describe the present disclosure, parts or portions that are irrelevant to the description are omitted, and identical or similar constituent elements throughout the specification are denoted by the same reference numerals. In a flowchart described with reference to the drawings, an order of operations may be changed, several operations may be merged, a certain operation may be divided, and a specific operation may not be performed.

In addition, a singular form may be intended to include a plural form as well, unless an explicit expression such as “one” or “single” is used. As used herein, the singular forms “a,” “an” and “the” are intended to include the plural forms as well, unless the context clearly indicates otherwise. Terms including ordinal numbers such as “first” and “second” may be used only to describe various constituent elements, and should not be interpreted as limiting the constituent elements. The terms may be used for a purpose of distinguishing one constituent element from another constituent element.

Terms such as “unit”, “module”, “member”, and “block” may be embodied as hardware or software. As used herein, a plurality of “units”, “modules”, “members”, and “blocks” may be implemented as a single component, or a single “unit”, “module”, “member”, and “block” may include a plurality of components.

It will be understood that when an element is referred to as being “connected” with or to another element, it can be directly or indirectly connected to the other element, wherein the indirect connection includes “connection via a wireless communication network”.

Also, when a part “includes” or “comprises” an element, unless there is a particular description contrary thereto, the part may further include other elements, not excluding the other elements.

Throughout the description, when a member is “on” another member, this includes not only when the member is in contact with the other member, but also when there is another member between the two members.

As used herein, the expressions “at least one of a, b or c” and “at least one of a, b and c” indicate “only a,” “only b,” “only c,” “both a and b,” “both a and c,” “both b and c,” and “all of a, b, and c.”

Hereinafter, the present disclosure will be described in more detail through examples. The examples are intended only to exemplify the present disclosure, and the scope of protection of right of the present disclosure is not limited by the examples.

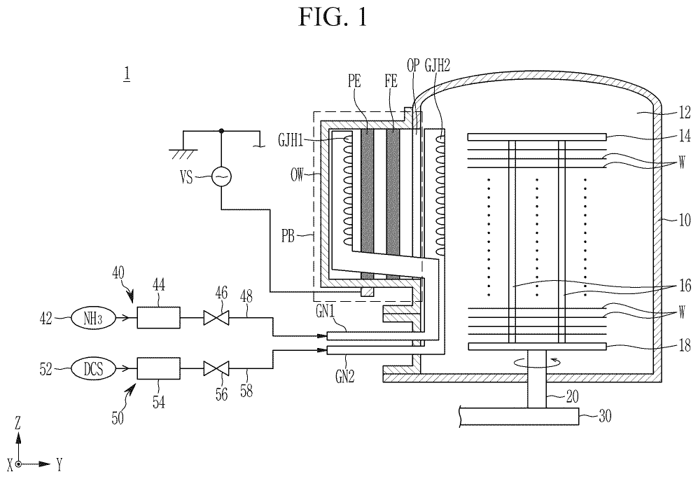

FIG. 1 is a diagram illustrating a substrate processing apparatus according to one or more embodiments of the present disclosure.

Referring to FIG. 1, the substrate processing apparatus 1 may include a reaction vessel 10, a rotation axis 20, an elevation instrument 30, a first processing gas supply system 40, a second processing gas supply system 50, and a plasma box PB.

The substrate processing apparatus 1 may include a processing area 12 provided within the reaction vessel 10, so that it includes a wafer boat 14 and a table 18 capable of accommodating and stacking a plurality of wafers W in multiple stages, and a supporting member 16 supporting the wafer boat 14 and the table 18. The number of the wafers W accommodated and stacked in the wafer boat 14 and the table 18 may be 100 to 120, but the disclosure is not limited thereto. For example, the reaction vessel 10 may have a cylindrical shape, and may be formed of quartz.

A first processing gas including ammonia (NH₃), that is a nitride gas, may be provided in the processing area 12 from the first processing gas supply system 40, and dichlorosilane (DCS), that is a silane-based gas, may be provided in the processing area 12 from the second processing gas supply system 50. The substrate processing apparatus 1 may be configured to form a silicon nitride (SiN) film on the wafers W using an ammonia gas and a dichlorosilane gas within the processing area 12.

The rotation axis 20 may be coupled to the table 18. The rotation axis 20 may rotate the wafers W accommodated in the wafer boat 14 at a constant speed so that a silicon nitride film is uniformly formed along a radial direction of the wafers W.

The elevation instrument 30 may be connected to a lower portion of the rotation axis 20. The elevation instrument 30 may be moved up and down, and thus the plurality of wafers W accommodated in the wafer boat 14 may be collectively moved up and down.

The first processing gas supply system 40 and the second processing gas supply system 50 for supplying predetermined processing gases to the processing area 12 may be connected to a side surface of the reaction vessel 10.

The first processing gas supply system 40 may include a first processing gas storage 42, a first processing gas flow amount controller 44, a first opening/closing valve 46, and a first processing gas supply line 48. The second processing gas supply system 50 may include a second processing gas storage 52, a second processing gas flow amount controller 54, a second opening/closing valve 56, and a second processing gas supply line 58.

The first processing gas supply system 40 may supply the first processing gas including ammonia (NH₃) that is the nitride gas. Specifically, the first processing gas supply system 40 may move the first processing gas stored in the first processing gas storage 42 through the first processing gas supply line 48, and may supply the first processing gas to the plasma box PB through a first gas nozzle GN1 connected to the first processing gas supply line 48.

The second processing gas supply system 50 may supply the second processing gas including a DCS gas that is the silane-based gas. Specifically, the second processing gas supply system 50 may move the second processing gas stored in the second processing gas storage 52 through the second processing gas supply line 58, and may supply the second processing gas into the reaction vessel 10 through a second gas nozzle GN2 connected to the second processing gas supply line 58.

A supply flow amount of the first processing gas may be controlled by the first processing gas flow amount controller 44 and the first opening/closing valve 46. A supply flow amount of the second processing gas may be controlled by the second processing gas flow amount controller 54 and the second opening/closing valve 56.

For example, the first gas nozzle GN1 and the second gas nozzle GN2 may be formed of a quartz tube, and the first processing gas and the second processing gas may be respectively injected through a plurality of first gas injection holes GJH1 and a plurality of second gas injection holes GJH2.

The first gas nozzle GN1 may extend along a height direction (i.e., Z direction) of the reaction vessel 10, and the plurality of first gas injection holes GJH1 may be formed to be spaced apart at a predetermined interval so that the first processing gas is injected (or sprayed) throughout the wafers W above the wafer boat 14. The second gas nozzle GN2 may also extend along the height direction of the reaction vessel 10, and the plurality of second gas injection holes GJH2 may be formed to be spaced apart at a predetermined interval so that the second processing gas is injected (or sprayed) onto and throughout the wafers W.

The first processing gas may be supplied through the plurality of first gas injection holes GJH1 of the first gas nozzle GN1 to form a gas flow parallel with the plurality of wafers W above the wafer boat 14. A high frequency power source VS may be maintained in a turned-on state over a supply time of the first processing gas.

The second processing gas may be supplied through the plurality of second gas injection holes GJH2 of the second gas nozzle GN2 to form a gas flow parallel with the plurality of wafers W above the wafer boat 14. The second processing gas may be activated and decomposed by a heating temperature of the processing area 12, and a molecule or an atom of a decomposition product of the second processing gas may be adsorbed on the plurality of wafers W.

The first processing gas and the second processing gas may be supplied as the wafer boat 14 rotates by rotation of the rotation axis 20. The first processing gas and the second processing gas may be alternately supplied, and for example, the supply cycle may be repeated 400 times for 6 hours. A thin film of silicon nitride may be formed and stacked on the plurality of wafers W for each cycle.

The plasma box PB may be disposed along a height direction of the reaction vessel 10 on a side surface of the reaction vessel 10. The plasma box PB may include the first gas nozzle GN1 through which the first processing gas is injected, a plasma electrode PE and a floating electrode FE disposed in front of the first gas nozzle GN1 in a direction in which the first processing gas is injected, and an opening portion OP through which the first processing gas is injected into the processing area 12 from the plasma box PB. The plasma box PB may be separated from the outside through an outer wall OW.

The plasma electrode PE may extend along a height direction of the plasma box PB to ionize the first processing gas injected from the first gas nozzle GN1. A voltage may be applied to the plasma electrode PE by the high frequency power source VS.

The floating electrode FE may extend in a height direction of the plasma box PB similar to the plasma electrode PE. The plasma electrode PE and the floating electrode FE may be disposed on an outer surface of the outer wall OW. Unlike the plasma electrode PE, a voltage may not be applied to the floating electrode FE, and for example, the floating electrode FE may be disposed in a shape of a metal plate.

For example, a frequency of the high frequency power source VS may have a value of 1 MHz to 27.12 MHz, but the disclosure is not necessarily limited thereto. For example, 13.56 MHz may be used for the frequency of the high frequency power source VS, but the present disclosure is not limited thereto, and the frequency of the high frequency power source VS may be used within a range of 1 MHz to 27.12 MHz.

A voltage provided by the high frequency power source VS may be applied to the plasma electrode PE, and the plasma electrode PE may ionize the first processing gas through the application of the voltage provided by the high frequency power source VS. Specifically, the first processing gas injected through the first gas injection hole GJH1 may be excited and converted from a neutral gas state into plasma when passing through an electric field formed by the plasma electrode PE.

The floating electrode FE may be disposed adjacent to the plasma electrode PE to increase plasma efficiency. Specifically, a configuration where the floating electrode FE is disposed together with the plasma electrode PE may collect more electrons in the floating electrode FE compared with a case where only the plasma electrode PE is disposed, and thus more plasma may be formed.

That is, a configuration where the floating electrode FE is disposed together with the plasma electrode PE at the same radio frequency (RF) voltage may generate more plasma than a configuration where only the plasma electrode PE is disposed. Additionally, a configuration where the floating electrode FE is disposed together with the plasma electrode PE may generate substantially the same amount of plasma as a configuration where only the plasma electrode PE is disposed even with a relatively low radio frequency (RF) voltage. Thus, generation of a particle in the plasma box PB may be suppressed through the increased plasma efficiency.

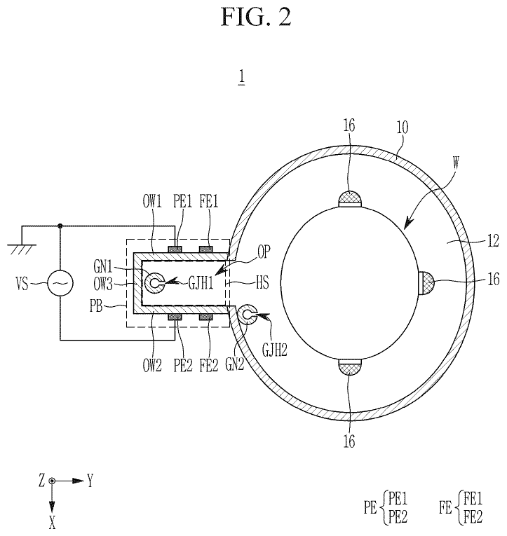

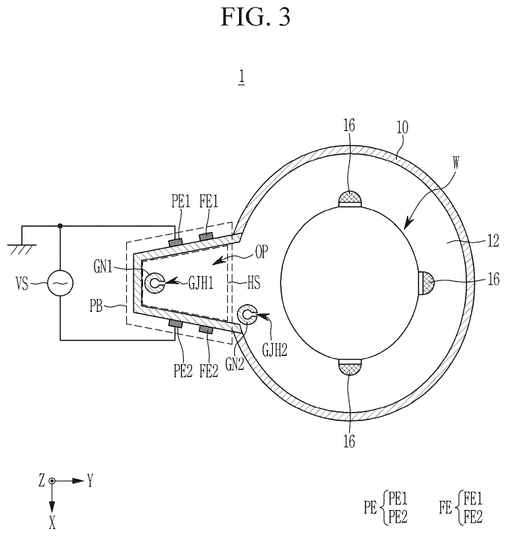

FIG. 2 and FIG. 3 are diagrams illustrating an X-Y cross-section of the substrate processing apparatus shown in FIG. 1.

Referring to FIG. 2, the plasma box PB may include a first outer wall OW1 disposed to extend in a Y direction, a second outer wall OW2 disposed to extend in the Y direction and facing the first outer wall OW1, and a third outer wall OW3 disposed to extend in an X direction and to connect first outer wall OW1 and second outer wall OW2. The plasma box PB may be separated from the outside through the first to third outer walls OW1-OW3, and a housing HS may be defined inside the plasma box PB by the first to third outer walls OW1-OW3.

The plasma electrode PE and the floating electrode FE may be disposed on outer surfaces of the first outer wall OW1 and the second outer wall OW2. Specifically, a first plasma electrode PE1 and a first floating electrode FE1 may be disposed on the outer surface of the first outer wall OW1, and a second plasma electrode PE2 and a second floating electrode FE2 may be disposed on the outer surface of the second outer wall OW2.

Although FIG. 2 shows that a cross-section of the plasma box PB has a rectangular shape, the disclosure is not necessarily limited thereto. For example, referring to FIG. 3, the plasma box PB may have a trapezoidal cross-section, or may have various cross-sections such as a semicircular shape and an elliptical shape according to one or more embodiments. However, for convenience of description, hereinafter, it will be described that the cross-section of the plasma box PB has a rectangular shape. Additionally, hereinafter, the plasma box PB may be referred to as a plasma generator.

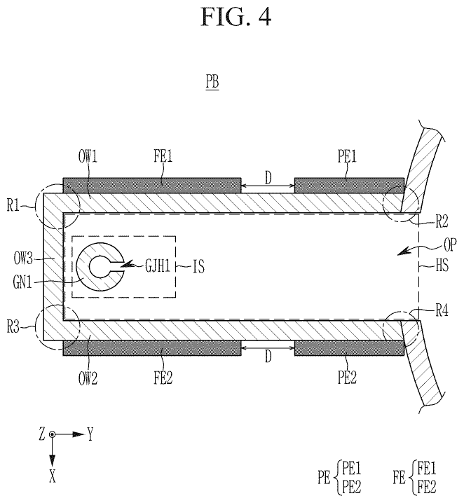

FIG. 4 is a diagram for describing the plasma generator according to one or more embodiments of the present disclosure.

Referring to FIG. 4, the plasma generator may include first to third outer walls OW1-OW3, and a housing HS defined by the first to third outer walls OW1-OW3.

The first outer wall OW1 may be disposed to extend in the Y direction from a first area R1 adjacent to the first gas nozzle GN1 to a second area R2 adjacent to an opening portion OP. The second outer wall OW2 may be disposed to extend in the Y direction from a third area R3 adjacent to the first gas nozzle GN1 to a fourth area R4 adjacent to the opening portion OP. The third outer wall OW3 may be disposed to extend in the X direction from the first area R1 to the third area R3.

The housing HS may include an internal space IS in which the first gas nozzle GN1 is provided, and may further include the opening portion OP through which the first processing gas injected through the first gas injection hole GJH1 passes to be supplied to the processing area 12 of FIG. 1.

The plasma electrode PE may be disposed on outer surfaces of the first outer wall OW1 and the second outer wall OW2. Specifically, a first plasma electrode PE1 may be disposed between the first area R1 and the second area R2. A second plasma electrode PE2 may face the first plasma electrode PE1, and may be disposed between the third area R3 and the fourth area R4.

The floating electrode FE may be disposed on the outer surfaces of the first outer wall OW1 and the second outer wall OW2. Specifically, a first floating electrode FE1 may be disposed between the first area R1 and the first plasma electrode PE1. A second floating electrode FE2 may face the first floating electrode FE1, and may be disposed between the third area R3 and the second plasma electrode PE2.

The first floating electrode FE1 and the first plasma electrode PE1 may be separated by a predetermined distance D. Similarly, the second floating electrode FE2 and the second plasma electrode PE2 may also be separated by the predetermined distance D. As a value of the predetermined distance D decreases, plasma efficiency of the plasma generator may increase.

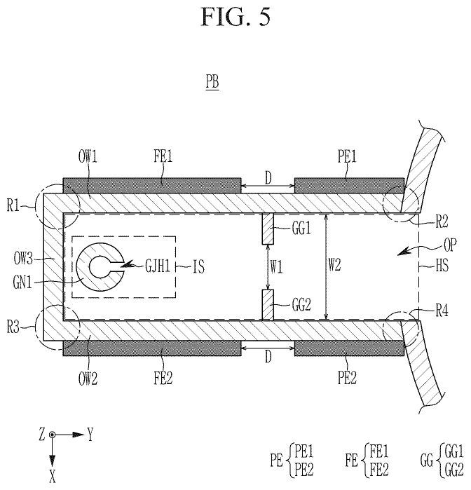

FIGS. 5 to 8 are diagrams for describing a plasma generator according to one or more embodiments of the present disclosure.

Referring to FIGS. 5 to 8, the plasma generator may further include a gas guide GG. The gas guide GG may be disposed on an inner surface of the housing HS between the first gas nozzle GN1 and the opening portion OP.

The gas guide GG may include a first gas guide GG1 and a second gas guide GG2 facing each other. The first gas guide GG1 and the second gas guide GG2 may be disposed to be spaced apart from each other by a predetermined width W1. The width W1 between the first gas guide GG1 and the second gas guide GG2 may be defined as a shortest separation distance between the first gas guide GG1 and the second gas guide GG2 according to a shape thereof.

The width W1 between the first gas guide GG1 and the second gas guide GG2 may be smaller than a width W2 along the X direction of the housing HS. The first processing gas injected from the first gas nozzle GN1 may pass through a relatively narrow width formed by the gas guide GG. As a result, a diffusion speed and a concentration of the first processing gas passing through the gas guide GG may be increased, and an amount of the first processing gas supplied to a central portion of the wafer W of FIG. 1 may be increased. Therefore, a deposition material may be more uniformly formed along the radial direction of the wafers W of FIG. 1.

A shape of the gas guide GG may be variously implemented so that the shortest separation distance between the first gas guide GG1 and the second gas guide GG2 is narrower than the width W2 along the X direction of the housing HS. In one or more embodiments, the gas guide GG may be a baffle.

Referring to FIG. 5, the first gas guide GG1 may include a first surface extending from a specific area of the inner surface of the housing HS along the X direction. The specific area of the inner surface of the housing HS may be an area corresponding to an interval between the first floating electrode FE1 and the first plasma electrode PE1.

The second gas guide GG2 may include a first surface extending from another specific area of the inner surface of the housing HS along −X direction. The other specific area of the inner surface of the housing HS may be an area corresponding to an interval between the second floating electrode FE2 and the second plasma electrode PE2.

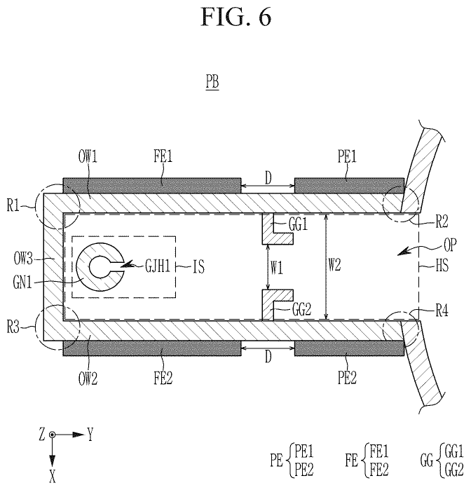

Referring to FIG. 6, a first gas guide GG1 may include a first surface extending from a specific area of an inner surface of the housing HS along the X direction, and a second surface extending along the Y direction. The specific area of the inner surface of the housing HS may be an area corresponding to an interval between the first floating electrode FE1 and the first plasma electrode PE1.

A second gas guide GG2 may include a first surface extending from another specific area of the inner surface of the housing HS along the −X direction, and a second surface extending along the Y direction. The other specific area of the inner surface of the housing HS may be an area corresponding to an interval between the second floating electrode FE2 and the second plasma electrode PE2.

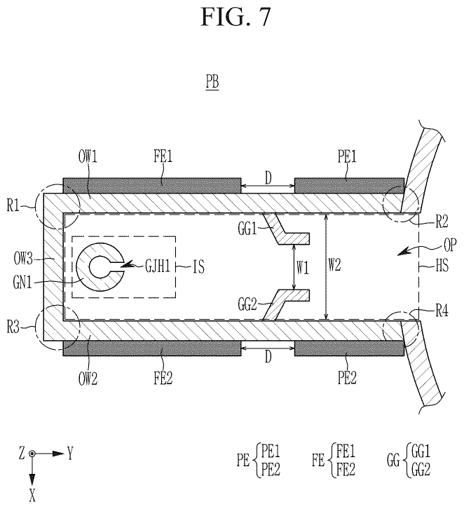

Referring to FIG. 7, a first gas guide GG1 may include a first surface extending from a specific area of an inner surface of the housing HS at an angle relative to the inner surface of the housing HS along a direction intersecting the X direction, and a second surface extending along the Y direction. In one or more embodiments, the angle between the first surface and the inner surface of the housing HS is not 90 degrees, and the second surface is parallel to the inner surface of the housing HS. The specific area of the inner surface of the housing HS may be an area corresponding to an interval between the first floating electrode FE1 and the first plasma electrode PE1.

A second gas guide GG2 may include a first surface extending from another specific area of the inner surface of the housing HS at an angle relative to the inner surface of the housing HS along a direction intersecting the X direction, and a second surface extending along the Y direction. In one or more embodiments, the angle between the first surface and the inner surface of the housing HS is not 90 degrees, and the second surface is parallel to the inner surface of the housing HS. The other specific area of the inner surface of the housing HS may be an area corresponding to an interval between the second floating electrode FE2 and the second plasma electrode PE2.

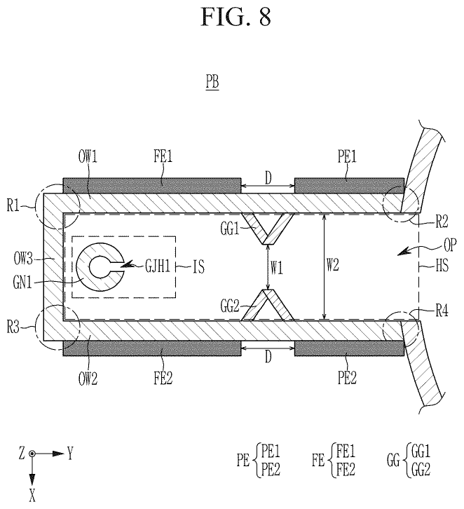

Referring to FIG. 8, a first gas guide GG1 may include a first surface extending from a specific area of an inner surface of the housing HS along a direction intersecting the X direction, and a second surface extending to an area adjacent to the specific area along a direction intersecting a direction in which the first surface extends. For example, the first and second surfaces may form a V-shape. The point at which the first surface and the second surface contact one another may correspond to an interval between the first floating electrode FE1 and the first plasma electrode PE1.

A second gas guide GG2 may include a first surface extending from another specific area of the inner surface of the housing HS along a direction intersecting the X direction, and a second surface extending to an area adjacent to the other specific area along a direction intersecting a direction in which the first surface extends. For example, the first and second surfaces may form a V-shape. The point at which the first surface and the second surface contact one another may correspond to an interval between the second floating electrode FE2 and the second plasma electrode PE2.

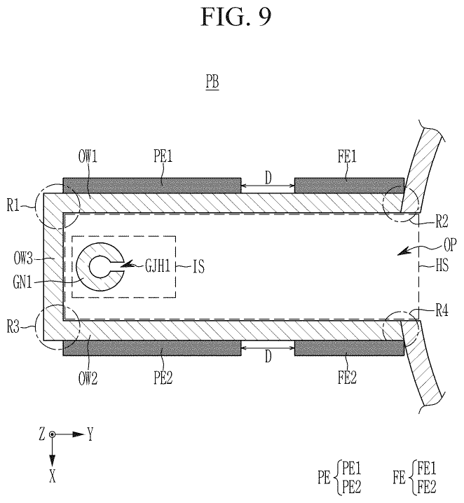

FIGS. 9 to 13 are diagrams for describing a plasma generator according to one or more embodiments of the present disclosure. Hereinafter, a difference between the embodiment illustrated in FIGS. 9 to 13 and the embodiment illustrated in FIGS. 4 to 8 will be mainly described.

Referring to FIG. 9, the plasma electrode PE may be disposed on outer surfaces of a first outer wall OW1 and a second outer wall OW2. Specifically, a first plasma electrode PE1 may be disposed between a first area R1 and a second area R2. A second plasma electrode PE2 may face the first plasma electrode PE1 and may be disposed between a third area R3 and a fourth area R4.

The floating electrode FE may be disposed on the outer surfaces of the first outer wall OW1 and the second outer wall OW2. Specifically, a first floating electrode FE1 may be disposed between the second area R2 and the first plasma electrode PE1. A second floating electrode FE2 may face the first floating electrode FE1 and may be disposed between the fourth area R4 and the second plasma electrode PE2. That is, a disposition relationship between the plasma electrode PE and the floating electrode FE shown in FIG. 9 may be opposite to a disposition relationship between the plasma electrode PE and the floating electrode FE shown in FIG. 4.

The first plasma electrode PE1 and the first floating electrode FE1 may be separated by a predetermined distance D. Similarly, the second plasma electrode PE2 and the second floating electrode FE2 may also be separated by the predetermined distance D. As a value of the predetermined distance D decreases, plasma efficiency of the plasma generator may increase.

Even in a disposition of the plasma electrode PE and the floating electrode FE shown in FIG. 9, a shape of the gas guide GG may be variously implemented so that the shortest separation distance between the first gas guide GG1 and the second gas guide GG2 is narrower than the width W2 along the X direction of the housing HS. Again, the gas guide GG may be a baffle.

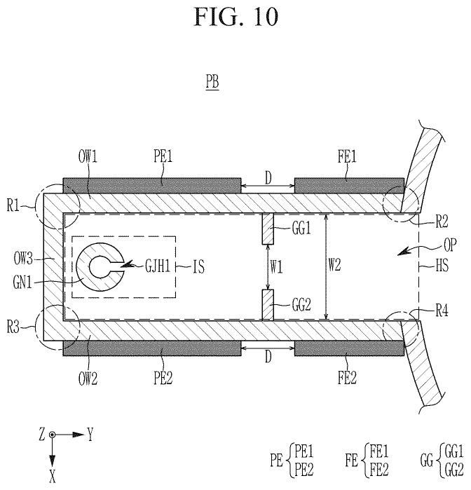

Referring to FIG. 10, the first gas guide GG1 may include a first surface extending from a specific area of an inner surface of the housing HS along the X direction. The specific area of the inner surface of the housing HS may be an area corresponding to an interval between the first plasma electrode PE1 and the first floating electrode FE1.

The second gas guide GG2 may include a first surface extending from another specific area of the inner surface of the housing HS along the −X direction. The other specific area of the inner surface of the housing HS may be an area corresponding to an interval between the second plasma electrode PE2 and the second floating electrode FE2.

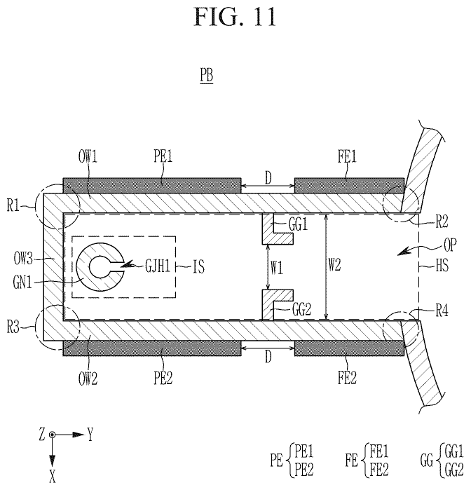

Referring to FIG. 11, a first gas guide GG1 may include a first surface extending from a specific area of an inner surface of the housing HS along the X direction, and a second surface extending along the Y direction. The specific area of the inner surface of the housing HS may be an area corresponding to an interval between the first plasma electrode PE1 and the first floating electrode FE1.

A second gas guide GG2 may include a first surface extending from another specific area of the inner surface of the housing HS along the −X direction, and a second surface extending along the Y direction. The other specific area of the inner surface of the housing HS may be an area corresponding to an interval between the second plasma electrode PE2 and the second floating electrode FE2.

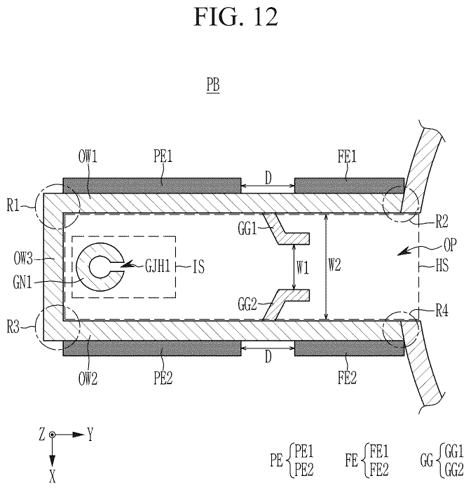

Referring to FIG. 12, a first gas guide GG1 may include a first surface extending from a specific area of an inner surface of the housing HS at an angle relative to the inner surface of the housing HS along a direction intersecting the X direction, and a second surface extending along the Y direction. In one or more embodiments, the angle between the first surface and the inner surface of the housing HS is not 90 degrees, and the second surface is parallel to the inner surface of the housing HS. The specific area of the inner surface of the housing HS may be an area corresponding to an interval between the first plasma electrode PE1 and the first floating electrode FE1.

A second gas guide GG2 may include a first surface extending from another specific area of the inner surface of the housing HS at an angle relative to the inner surface of the housing HS along a direction intersecting the X direction, and a second surface extending along the Y direction. In one or more embodiments, the angle between the first surface and the inner surface of the housing HS is not 90 degrees, and the second surface is parallel to the inner surface of the housing HS. The other specific area of the inner surface of the housing HS may be an area corresponding to an interval between the second plasma electrode PE2 and the second floating electrode FE2.

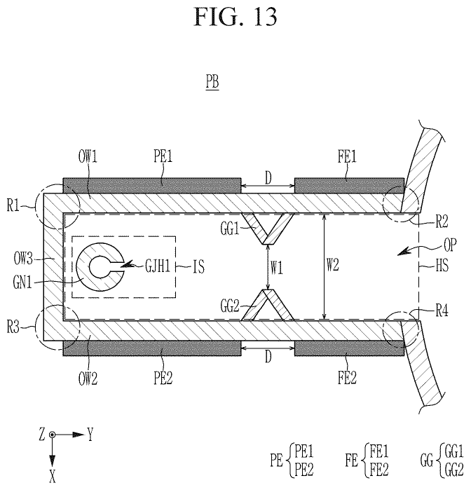

Referring to FIG. 13, a first gas guide GG1 may include a first surface extending from a specific area of an inner surface of the housing HS along a direction intersecting the X direction, and a second surface extending to an area adjacent to the specific area along a direction intersecting a direction in which the first surface extends. For example, the first and second surfaces may form a V-shape. The point at which the first surface and the second surface contact one another may correspond to an interval between the first plasma electrode PE1 and the first floating electrode FE1.

A second gas guide GG2 may include a first surface extending from another specific area of the inner surface of the housing HS along a direction intersecting the X direction, and a second surface extending to an area adjacent to the other specific area along a direction intersecting a direction in which the first surface extends. For example, the first and second surfaces may form a V-shape. The point at which the first surface and the second surface contact one another may correspond to an interval between the second plasma electrode PE2 and the second floating electrode FE2.

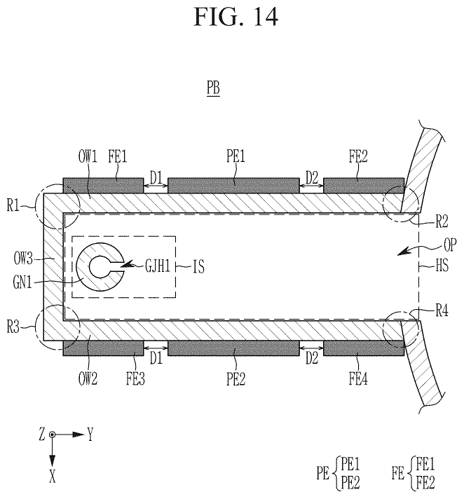

FIGS. 14 to 18 are diagrams for describing a plasma generator according to one or more embodiments of the present disclosure. Hereinafter, a difference between the embodiment illustrated in FIGS. 14 to 18, the embodiment illustrated in FIGS. 9 to 13, and the embodiment illustrated in FIGS. 4 to 8 will be mainly described.

Referring to FIG. 14, the plasma electrode PE may be disposed on outer surfaces of a first outer wall OW1 and a second outer wall OW2. Specifically, a first plasma electrode PE1 may be disposed between a first area R1 and a second area R2. A second plasma electrode PE2 may face the first plasma electrode PE1, and may be disposed between a third area R3 and a fourth area R4.

The floating electrode FE may be disposed on the outer surfaces of the first outer wall OW1 and the second outer wall OW2. Specifically, a first floating electrode FE1 may be disposed between the first area R1 and the first plasma electrode PE1. A second floating electrode FE2 may be disposed between the second area R2 and the first plasma electrode PE1. A third floating electrode FE3 may face the first floating electrode FE1, and may be disposed between the third area R3 and the second plasma electrode PE2. A fourth floating electrode FE4 may face the second floating electrode FE2, and may be disposed between the fourth area R4 and the second plasma electrode PE2.

The first plasma electrode PE1 and the first floating electrode FE1 may be separated by a first predetermined distance D1. Similarly, the second plasma electrode PE2 and the third floating electrode FE3 may also be separated by the first predetermined distance D1. As a value of the first predetermined distance D1 decreases, plasma efficiency of the plasma generator may increase.

The first plasma electrode PE1 and the second floating electrode FE2 may be separated by a second predetermined distance D2. Similarly, the second plasma electrode PE2 and the fourth floating electrode FE4 may also be separated by the second predetermined distance D2. As a value of the second predetermined distance D2 decreases, plasma efficiency of the plasma generator may increase.

The first predetermined distance D1 and the second predetermined distance D2 may have different values, but the disclosure is not necessarily limited thereto, and the first predetermined distance D1 and the second predetermined distance D2 may have the same value.

Even in a disposition of the plasma electrode PE and the floating electrode FE shown in FIG. 14, a shape of the gas guide GG may be variously implemented so that the shortest separation distance between the first gas guide GG1 and the second gas guide GG2 is narrower than the width W2 along the X direction of the housing HS. Again, the gas guide GG may be a baffle.

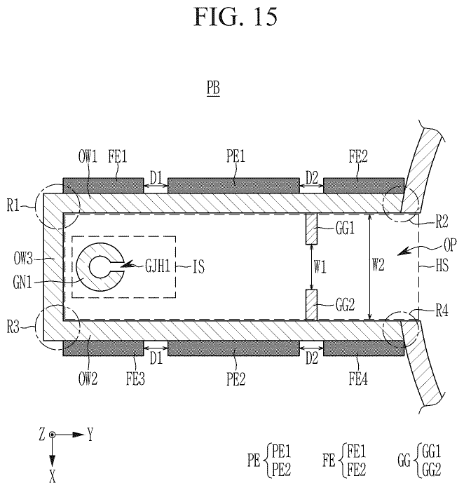

Referring to FIG. 15, the first gas guide GG1 may include a first surface extending from a specific area of an inner surface of the housing HS along the X direction. The specific area of the inner surface of the housing HS may be an area corresponding to an interval between the first plasma electrode PE1 and the second floating electrode FE2.

The second gas guide GG2 may include a first surface extending from another specific area of the inner surface of the housing HS along the −X direction. The other specific area of the inner surface of the housing HS may be an area corresponding to an interval between the second plasma electrode PE2 and the fourth floating electrode FE4.

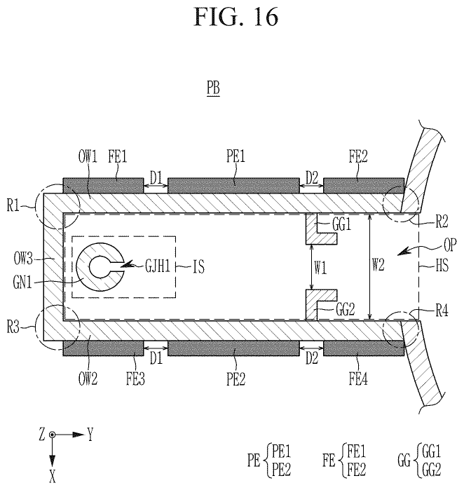

Referring to FIG. 16, a first gas guide GG1 may include a first surface extending from a specific area of an inner surface of the housing HS along the X direction, and a second surface extending along the Y direction. The specific area of the inner surface of the housing HS may be an area corresponding to an interval between the first plasma electrode PE1 and the second floating electrode FE2.

A second gas guide GG2 may include a first surface extending from another specific area of the inner surface of the housing HS along the −X direction, and a second surface extending along the Y direction. The other specific area of the inner surface of the housing HS may be an area corresponding to an interval between the second plasma electrode PE2 and the fourth floating electrode FE4.

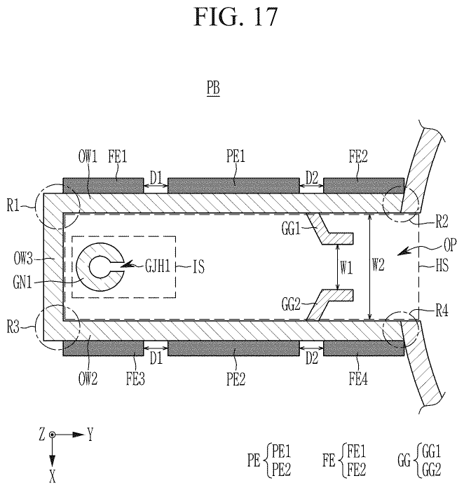

Referring to FIG. 17, a first gas guide GG1 may include a first surface extending from a specific area of an inner surface of the housing HS at an angle relative to the inner surface of the housing HS along a direction intersecting the X direction, and a second surface extending along the Y direction. In one or more embodiments, the angle between the first surface and the inner surface of the housing HS is not 90 degrees, and the second surface is parallel to the inner surface of the housing HS. The specific area of the inner surface of the housing HS may be an area corresponding to an interval between the first plasma electrode PE1 and the second floating electrode FE2.

A second gas guide GG2 may include a first surface extending from another specific area of the inner surface of the housing HS at an angle relative to the inner surface of the housing HS along a direction intersecting the X direction, and a second surface extending along the Y direction. In one or more embodiments, the angle between the first surface and the inner surface of the housing HS is not 90 degrees, and the second surface is parallel to the inner surface of the housing HS. The other specific area of the inner surface of the housing HS may be an area corresponding to an interval between the second plasma electrode PE2 and the fourth floating electrode FE4.

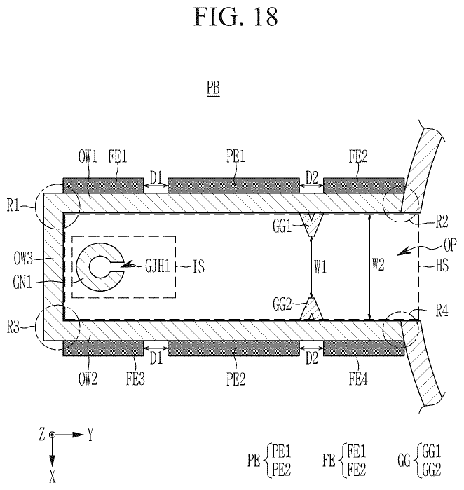

Referring to FIG. 18, a first gas guide GG1 may include a first surface extending from a specific area of an inner surface of the housing HS along a direction intersecting the X direction, and a second surface extending to an area adjacent to the specific area along a direction intersecting a direction in which the first surface extends. For example, the first and second surfaces may form a V-shape. The point at which the first surface and the second surface contact one another may correspond to an interval between the first plasma electrode PE1 and the second floating electrode FE2.

A second gas guide GG2 may include a first surface extending from another specific area of the inner surface of the housing HS along a direction intersecting the X direction, and a second surface extending to an area adjacent to the other specific area along a direction intersecting a direction in which the first surface extends. For example, the first and second surfaces may form a V-shape. The point at which the first surface and the second surface contact one another may correspond to an interval between the second plasma electrode PE2 and the fourth floating electrode FE4.

In FIGS. 15 to 18, the gas guide GG is illustrated as being disposed between the first plasma electrode PE1 and the second floating electrode FE2 and between the second plasma electrode PE2 and the fourth floating electrode FE4, but the disclosure is not necessarily limited thereto.

For example, the gas guide GG may be disposed between the first plasma electrode PE1 and the first floating electrode FE1 and between the second plasma electrode PE2 and the third floating electrode FE3. Alternatively, the gas guide GG may be disposed between the first plasma electrode PE1 and the first floating electrode FE1, between the first plasma electrode PE1 and the second floating electrode FE2, between the second plasma electrode PE2 and the third floating electrode FE3, and between the second plasma electrode PE2 and the fourth floating electrode FE4.

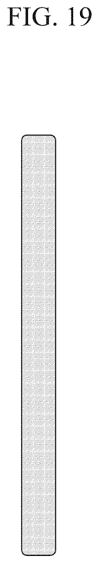

FIGS. 19 to 21 are diagrams for describing a shape of an electrode according to one or more embodiments of the present disclosure.

Referring to FIG. 19, both the plasma electrode and the floating electrode may include a metal plate. The plasma electrode and the floating electrode may have a shape of a metal plate. That is, the plasma electrode and the floating electrode may have the same shape.

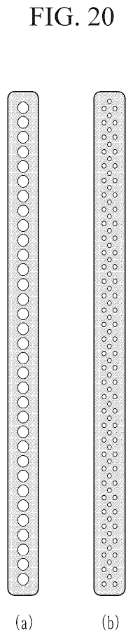

According to one or more embodiments, the plasma electrode and the floating electrode may have different shapes. The plasma electrode has the shape of the metal plate illustrated in FIG. 19, but for example, the floating electrode may have a shape of a metal plate including a plurality of hollows, as shown in FIG. 20.

The floating electrode may have a metal plate shape including a hollow having a relatively large size, as shown in FIG. 20(a), or may have a metal plate shape including a hollow having a relatively small size, as shown in FIG. 20(b).

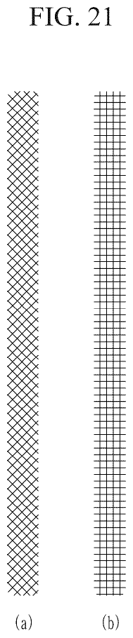

As another example, the plasma electrode may have the shape of the metal plate shown in FIG. 19, while the floating electrode has a shape of a metal mesh plate shown in FIG. 21. The floating electrode may have a metal mesh plate shape arranged in various directions, as shown in FIG. 21(a) and FIG. 21(b).

While this disclosure has been described in connection with what is presently considered to be practical embodiments, it should be understood that the disclosure is not limited to the disclosed embodiments, but, on the contrary, is intended to cover various modifications and equivalent arrangements included within the spirit and scope of the appended claims.

What is claimed is:

1. A plasma generator comprising:
a housing comprising an internal space and an opening through which plasma is emitted;
a gas nozzle in the internal space, wherein the gas nozzle is configured to inject a processing gas into the internal space;
a plurality of plasma electrodes on an outer surface of the housing and to which a voltage is applied; and
a plurality of floating electrodes on the outer surface of the housing and adjacent to the plurality of plasma electrodes.

2. The plasma generator of claim 1, wherein the plurality of plasma electrodes and the plurality of floating electrodes extend in a height direction of the housing.

3. The plasma generator of claim 2, wherein the plurality of plasma electrodes comprises:
a first plasma electrode between a first area adjacent to the gas nozzle and a second area adjacent to the opening; and
a second plasma electrode facing the first plasma electrode, wherein the second plasma electrode is between a third area adjacent to the gas nozzle and a fourth area adjacent to the opening.

4. The plasma generator of claim 3, wherein the plurality of floating electrodes comprises:
a first floating electrode between the first area and the first plasma electrode; and
a second floating electrode facing the first floating electrode, wherein the second floating electrode is between the third area and the second plasma electrode.

5. The plasma generator of claim 3, wherein the plurality of floating electrodes comprises:
a first floating electrode between the second area and the first plasma electrode; and
a second floating electrode facing the first floating electrode, wherein the second floating electrode is between the fourth area and the second plasma electrode.

6. The plasma generator of claim 3, wherein the plurality of floating electrodes comprises:
a first floating electrode between the first area and the first plasma electrode;
a second floating electrode between the second area and the first plasma electrode;
a third floating electrode facing the first floating electrode, wherein the third floating electrode is between the third area and the second plasma electrode; and
a fourth floating electrode facing the second floating electrode, wherein the fourth floating electrode is between the fourth area and the second plasma electrode.

7. The plasma generator of claim 1, further comprising a gas guide on an inner surface of the housing between the gas nozzle and the opening.

8. The plasma generator of claim 7,
wherein the gas guide comprises a first gas guide and a second gas guide facing each other, and
wherein a minimum separation distance between the first gas guide and the second gas guide in a first direction is less than a width of the housing in the first direction.

9. The plasma generator of claim 8,
wherein the first gas guide comprises a first surface extending in the first direction from an area of the inner surface of the housing, and
wherein the second gas guide comprises a first surface extending along a direction opposite to the first direction from another area of the inner surface of the housing.

10. The plasma generator of claim 8,
wherein the first gas guide comprises a first surface extending in the first direction from an area of the inner surface of the housing and a second surface extending in a second direction intersecting the first direction, and
wherein the second gas guide comprises a first surface extending in a direction opposite to the first direction from another area of the inner surface of the housing and a second surface extending in the second direction.

11. The plasma generator of claim 8,
wherein the first gas guide comprises a first surface extending from an area of the inner surface of the housing in a second direction intersecting the first direction and a second surface extending in a third direction intersecting the second direction, and
wherein the second gas guide comprises a first surface extending from another area of the inner surface of the housing in a fourth direction intersecting the first direction and a second surface extending in the third direction.

12. The plasma generator of claim 8,
wherein the first gas guide comprises a first surface extending from a first area of the inner surface of the housing along a second direction intersecting the first direction and a second surface extending from an end of the first surface of the first gas guide to a second area adjacent to the first area of the inner surface of the housing along a third direction intersecting the second direction, and
wherein the second gas guide comprises a first surface extending from a third area of the inner surface of the housing along a fourth direction intersecting the first direction and a second surface extending from an end of the first surface of the second gas guide to a fourth area adjacent to the other area of the inner surface of the housing along a fifth direction intersecting the fourth direction.

13. The plasma generator of claim 7,
wherein a plasma electrode of the plurality of plasma electrodes and a floating electrode of the plurality of floating electrodes are separated by a predetermined interval, and
wherein the gas guide comprises a first gas guide on the inner surface of the housing corresponding to the predetermined interval.

14. The plasma generator of claim 1,
wherein each of the plurality of plasma electrodes comprises a metal plate, and
wherein each of the plurality of floating electrodes comprises one of a metal plate, a metal plate comprising a plurality of hollows, and a metal mesh plate.

15. A plasma generator comprising:
a first outer wall extending in a first direction from a first area to a second area;
a second outer wall parallel to the first outer wall and extending in from a third area to a fourth area;
a third outer wall extending in a second direction from the first area to the third area, wherein the second direction intersects the first direction;
a gas nozzle in an inner space formed by the first, the second, and the third outer walls, wherein the gas nozzle is configured to inject a processing gas into the inner space;
a first plasma electrode on an outer surface of the first outer wall and a second plasma electrode on an outer surface of the second outer wall, wherein a voltage is applied to the first and the second plasma electrodes;
a first floating electrode on the outer surface of the first outer wall and a second floating electrode on the outer surface of the second outer wall, wherein the first floating electrode is adjacent to the first plasma electrode and the second floating electrode is adjacent to the second plasma electrode; and
a gas guide on inner surfaces of the first outer wall and the second outer wall.

16. A substrate processing apparatus comprising:
a reaction vessel;
a wafer boat in the reaction vessel and configured to hold one or more wafers; and
a plasma generator configured to generate plasma, wherein the plasma generator comprises:
a housing comprising an internal space and an opening through which the plasma is emitted into the reaction vessel;
a gas nozzle in the internal space, wherein the gas nozzle is configured to inject a processing gas into the internal space;
a plurality of plasma electrodes on an outer surface of the housing and to which a voltage is applied; and
a plurality of floating electrodes on an outer surface of the housing and adjacent to the plurality of plasma electrodes.

17. The substrate processing apparatus of claim 16, wherein the plurality of plasma electrodes comprises:
a first plasma electrode between a first area adjacent to the gas nozzle and a second area adjacent to the opening; and
a second plasma electrode facing the first plasma electrode, wherein the second plasma electrode is between a third area adjacent to the gas nozzle and a fourth area adjacent to the opening.

18. The substrate processing apparatus of claim 17, wherein the plurality of floating electrodes comprises:
a first floating electrode between the first area and the first plasma electrode; and
a second floating electrode facing the first floating electrode, wherein the second floating electrode is between the third area and the second plasma electrode.

19. The substrate processing apparatus of claim 17, wherein the plurality of floating electrodes comprises:
a first floating electrode between the second area and the first plasma electrode; and
a second floating electrode facing the first floating electrode, wherein the second floating electrode is between the fourth area and the second plasma electrode.

20. The substrate processing apparatus of claim 16, further comprising a first gas guide and a second gas guide on an inner surface of the housing,
wherein the first gas guide and the second gas guide are between the gas nozzle and the opening and are facing each other, and
wherein a minimum separation distance between the first gas guide and the second gas guide in a first direction is less than a width of the housing in the first direction.
